(19) United States
(12) Patent Application Publication
(10) Pub. No.: US 2008/0124880 A1
(43) Pub. Date: May 29, 2008

(54) FET STRUCTURE USING DISPOSABLE SPACER AND STRESS INDUCING LAYER

(75) Inventors: Wenhe Lin, Singapore (SG); Randy William Mann, Poughquag, NY (US); Padraic C. Shafer, Berkeley, CA (US); Christopher Vincent Baiocco, Newburgh, NY (US); Zhijoing Luo, Carmel, NY (US); Haining S. Yang, Wappingers Falls, NY (US); Xiangdong Chen, Poughquag, NY (US)

Correspondence Address: HORIZON IP PTE LTD, 7500A Beach Road, #04-306/308 The Plaza, SINGAPORE 199591, omitted

(73) Assignees: Chartered Semiconductor Manufacturing Ltd., Singapore (SG); International Business Machines Corporation, Armonk, NY (US)

(21) Appl. No.: 11/534,651

(22) Filed: Sep. 23, 2006

(51) Int. Cl. H01L 21/336

(52) U.S. Cl. 438/305; 257/E21.437

(57) ABSTRACT

Some non-limiting example embodiments comprise a disposable spacer formation and removal process and a stress capping layer process. We provide a gate structure over a substrate. We form disposable spacers abutting the at least one gate sidewall. We form S/D regions adjacent the disposable spacers. We remove the disposable spacers. We can form silicide regions over the S/D and gate. In an aspect, we can deposit a stress inducing layer over the gate and surface portions of the substrate adjacent to the gate, wherein the stress inducing liner provides a stress to a portion of the substrate underlying the gate electrode.

### BACKGROUND OF INVENTION

1) Field of the Invention

This invention relates generally to methods and semiconductor devices having disposable spacers, and more particularly, to FET semiconductor devices that can include a silicon (Si)-containing layer having enhanced electron and hole mobilities and disposable spacers.

2) Description of the Prior Art

We can form an integrated circuit by creating one or more devices (e.g., circuit components) on a semiconductor substrate using a fabrication process. As fabrication processes and materials improve, semiconductor device geometries have continued to decrease in size. For example, current fabrication processes are producing devices having geometry sizes (or feature size. e.g., the smallest component (or line) that may be created using the process) of less than 90 nm. Scaling progress in fabrication brings in benefits of high integration density and low fabrication cost.

Mechanical stresses are known to play a role in charge carrier mobility which affects Voltage threshold and drive current (Id). The effect of induced strain in a channel region of a CMOS device by mechanical stresses affects several critical device performance characteristics including drive current (Id) and particularly drive current saturation levels (IDsat), believed to be related to alteration in charge carrier mobilities caused by complex physical processes

Since it has become increasingly difficult to improve MOSFETs and therefore CMOS performance through continued simple geometry scaling, methods for improving performance without scaling have become critical. One approach for doing this is to increase carrier (electron and/or hole) mobilities. Increased carrier mobility can be obtained, for example, by introducing the appropriate stress into the Si lattice.

The application of stress changes the lattice dimensions of the silicon (Si)-containing substrate. By changing the lattice dimensions, the electronic band structure of the material is changed as well. This results in changes in carrier transport properties, which can be dramatic in certain cases. The application of stress can be used to enhance the performance of devices fabricated on the Si-containing substrates.

Compressive longitudinal stress along the channel increases drive current in p-type field effect transistors (pFETs) and decreases drive current in n-type field effect transistors (nFETs). Tensile longitudinal stress along the channel increases drive current in nFETs and decreases drive current in pFETs.

Nitride liners positioned atop field effect transistors (FETs) have been proposed as a means to provide stress based device improvements. However, further improvements can be done to improve device performance.

### SUMMARY OF THE INVENTION

The following presents a simplified summary in order to provide a basic understanding of some aspects of some example embodiments of the invention. This summary is not an extensive overview of the example embodiments or the invention. It is intended neither to identify key or critical elements of the invention nor to delineate the scope of the invention. Rather, the primary purpose of the summary is to present some example concepts of the invention in a simplified form as a prelude to the more detailed description that is presented later.

Some non-limiting example embodiments of the present invention provide structures and methods of manufacturing a semiconductor device which are characterized below and in the specification and claims.

An example embodiment method of forming a semiconductor device comprises:
forming at least a gate electrode over a substrate; gate electrode having gate sidewalls;
forming first sidewall spacers over the gate sidewalls;
forming disposable spacers over the sidewalls of the first sidewall spacers;
forming source and drain regions in substrate;
removing disposable spacers;
forming S/D silicide regions over source and drain regions,
depositing a stress inducing layer over gate electrode, and source and drain regions, wherein stress inducing layer provides a stress to a portion of substrate underlying gate electrode.
   An aspect the method of further comprises:
forming a (ILD) dielectric layer over the substrate.
   An aspect the method further comprises:
the disposable spacers are comprised of photoresist, resist, organic material, or anti-reflective coating (ARC) material.

An aspect the method further comprises:
the disposable spacers are comprised of a resist material;
the removal of the disposable spacer comprises an ashing process.

The above and below advantages and features are of representative embodiments only, and are not exhaustive and/or exclusive. They are presented only to assist in understanding the invention. It should be understood that they are not representative of all the inventions defined by the claims, to be considered limitations on the invention as defined by the claims, or limitations on equivalents to the claims. For instance, some of these advantages may be mutually contradictory, in that they cannot be simultaneously present in a single embodiment. Similarly, some advantages are applicable to one aspect of the invention, and inapplicable to others. Furthermore, certain aspects of the claimed invention have not been discussed herein. However, no inference should be drawn regarding those discussed herein relative to those not discussed herein other than for purposes of space and reducing repetition. Thus, this summary of features and advantages should not be considered dispositive in determining equivalence. Additional features and advantages of the invention will become apparent in the following description, from the drawings, and from the claims.

### BRIEF DESCRIPTION OF THE DRAWINGS

The features and advantages of a semiconductor device according to the present invention and further details of a process of fabricating such a semiconductor device in accordance with the present invention will be more clearly understood from the following description taken in conjunction with the accompanying drawings in which like reference numerals designate similar or corresponding elements, regions and portions and in which:

FIGS. 1, 2, 3A, 3B through 7A and 7B are cross sectional views for illustrating a method for manufacturing a semiconductor device according to an example embodiment of the present invention.

FIGS. 3B and 7B are cross sectional view for illustrating a method for manufacturing a semiconductor device according to an example embodiment of the present invention. FIGS. 3B and 7B shows an option where the spacers 20 are formed of 2 layers.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE EXAMPLE EMBODIMENTS

The example embodiments of the present invention will be described in detail with reference to the accompanying drawings. Some example embodiments provide a method of forming a transistor with disposable spacers and an overlying stress inducing layer.

In some non-limiting example embodiments of the invention, we present an advanced disposable spacer process combing easily removable organic disposable spacers and a stress capping layer over the gate structure. In an aspect the disposable spacers are comprised of organic material, such as photoresist. The example embodiments can be used to form both N and P type devices.

### First Example Embodiment

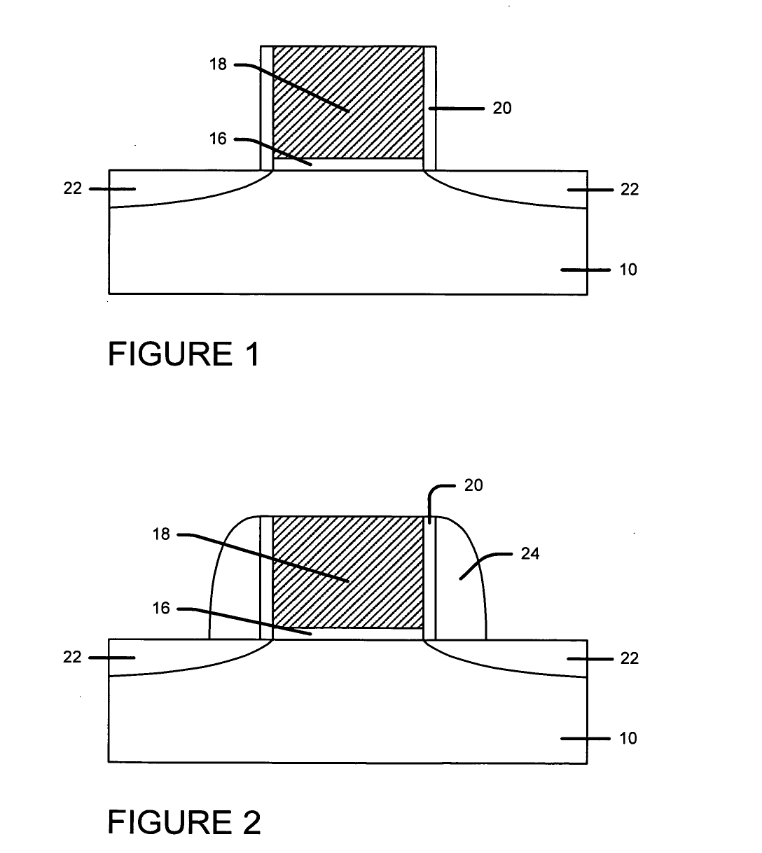

We provide at least a gate electrode over a substrate. We provide first sidewall spacers over the gate sidewalls. Below we describe in FIGS. 1, 2, 3A and 3B, one example method to achieve this.

Referring to FIG. 1, we form a gate dielectric layer 16 and a gate electrode 18 over a substrate 10.

Substrate 10 can comprise a silicon containing substrate, a silicon-on-insulator (SOI) or a germanium containing substrate and is more preferably a silicon substrate.

A gate dielectric layer 16 is preferably formed over the substrate. The gate dielectric 16 is preferably comprised of oxide, oxynitride or high-k material (K>3.0) and preferably has a thickness between 5 and 500 angstroms.

Gate electrode 18 is preferably comprised of polysilicon (poly), metal, silicide or SiGe or combination thereof, and is more preferably polysilicon (poly) as will be used for illustrative purpose hereafter. Gate electrode 18 can have a width of preferably from about 10 nm to 10 microns. Gate electrode 18 can have height of preferably from about 10 nm to 500 nm.

Isolation regions can be provided to separate different regions (e.g., PMOS regions and NMOS regions) of the substrate. Isolation regions are not shown to simply the drawings.

Form First Sidewall Spacers

Still referring to FIG. 1, we can form first sidewall spacers 20 over the gate sidewalls of the gate electrode 18.

The first sidewall spacers 20 can be comprised of a dielectric material such as oxide, silicon oxynitride or nitride.

The first spacers can be comprised of one or more spacers. The first spacers can be comprised of one or more layers.

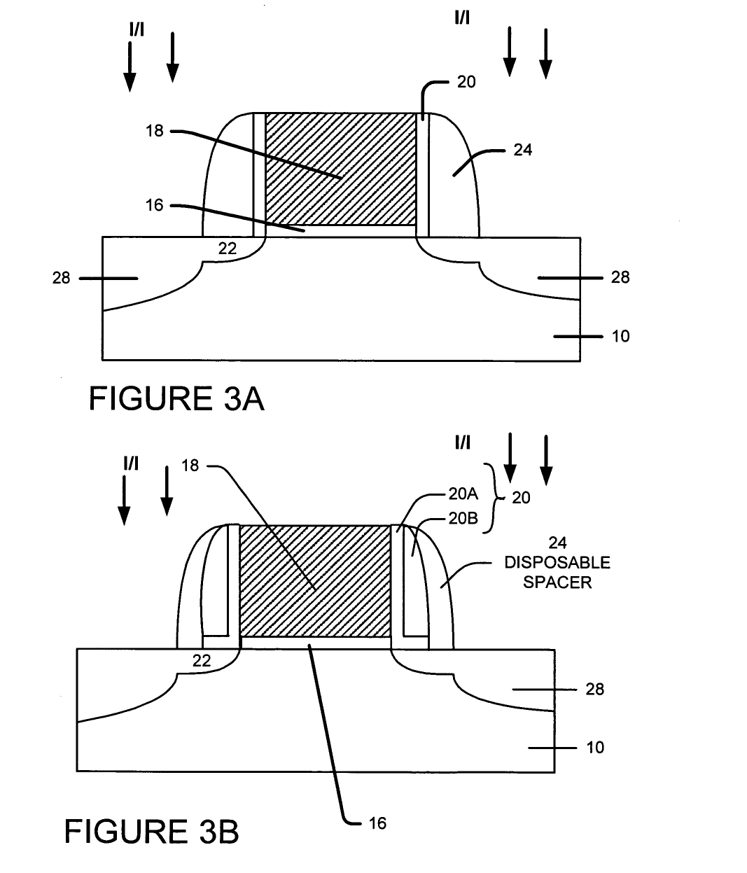

For example, FIG. 3B shows an option where the first spacers 20 are comprised of a first spacer 20A and a second spacer 20B. For example first and second spacers 20A 20B can be formed by forming a thin first dielectric layer and a second thicker dielectric layer. The first and second layers can be etched to form the spacers 20A 20B. The first spacer 20A can be comprised of oxide. The second spacer 20B can be comprised of nitride.

The first sidewall spacers (20 or 20A 20B) can be formed at different points in the processes and can be formed at different steps than shown in the figs. The spacers can be used to isolate the gate electrode from the subsequently formed source/drain silicide regions.

Form SDE or LDD Regions

Still referring to FIG. 1, we perform an ion implant to form SDE regions (or LDD regions) 22 approximately adjacent to the gate electrode in the substrate. The implant can be conducted into structure 10 adjacent and outboard of gate electrode to form SDE regions 22 having a depth of preferably from about 5 nm to 50 nm and more preferably from about 10 nm to 30 nm. The implant preferably uses As, B, BF₂, In, Xe, Ge, P, Si, F, N, or C atoms and more preferably uses As or B atoms. The implant can have a dose of preferably from about 1E10 to 1E16 atoms/cm2 and more preferably from about 1E12 to 1E15 atoms/cm2.

The device channel region is located in the substrate 10 between the SDE or LDD regions under the gate electrode.

Form Disposable Spacers

Referring to FIG. 2, we form disposable spacers 24 over the sidewalls of the gate electrode. The disposable spacers can be comprised of any suitable material.

The disposable spacers can be comprised of photoresist, organic material, or anti-reflective coating (ARC) organic material. The disposable spacers can be essentially 100% comprised of photoresist, organic material, or anti-reflective coating (ARC) organic material. For example, an Anti-Reflective Coating can be comprised of a material such as propylene glycol monomethyl ether,

The disposable spacers can be formed by forming an organic layer (such as a ARC layer) over the substrate and gate structure. Then we can anisotropically RIE etch the organic layer to form the disposable spacer over the gate sidewalls.

The disposable spacer can have a width between 10 and 1000 angstroms.

The disposable spacers are used to space the S/D regions further away from the gate.

If both NMOS and PMOS devices are being formed on a substrate, a masking layer (e.g., resist) can be formed to with openings over the regions where the subsequent p or n type S/D ion implant (I/I) is performed.

Form source and Drain Regions

Referring to FIG. 3A, we form source/drain regions 28 in the substrate approximately adjacent to the disposable spacers 24. The S/D regions are preferably formed using an implant using the disposable spacers as an implant mask.

The disposable spacers cause the S/D regions 28 which are to be formed subsequently to be spaced further away from the gate. The helps improve the short channel effect.

FIG. 3B shows the option we form disposable spacers 24 over the spacers 20A 20B over of the gate electrode. The remaining process steps can apply to the option where the spacer 20 is comprised of first and second spacers 20A 20B.

Remove the Disposable Spacers

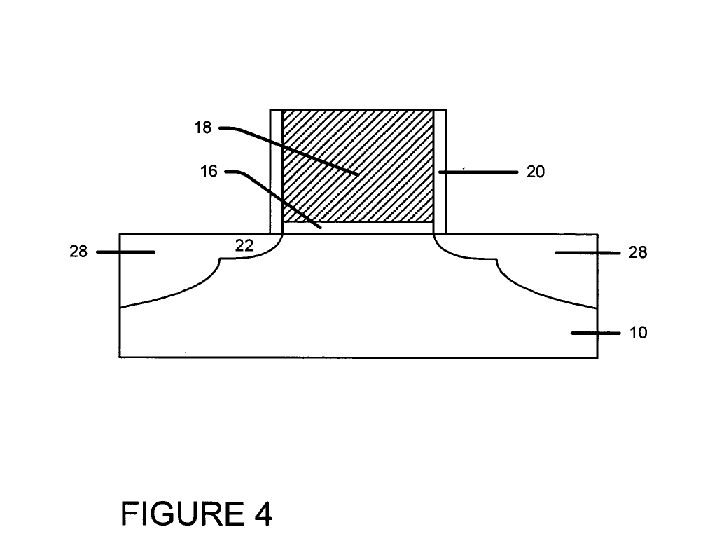

In a key step shown in FIG. 4, we remove the disposable spacers 24.

For disposable spacers comprised of an organic material, or comprised substantially of an organic material, we can use any process suitable for removing the organic material, such as (dry) plasma process, or wet etches.

For example, for disposable spacers 24 comprised of photoresist or ARC material, we can remove the disposable spacers using an ashing process. Ashing processes are used for resist strip process. Ashing processes typically use an oxygen containing plasma. We can also remove the disposable spacers 24 comprised of photoresist using resist strip processes, such as wet strip processes or dry (plasma) strip processes. If a resist mask was used for the P or N S/D ion implant (I/I), the resist mask can be removed in the same resist strip process as the disposable spacers. The same process above can be repeated for the N+ or P+ S/D implant, whichever hasn't taken place/

Compared to a reactive ion etch process or wet etching process for dielectric spacer removal, the embodiment's organic disposable spacers (e.g., resist) and simple ashing process, resist strip or its like process, is significantly simpler. The embodiments' ashing process or resist strip process has high selectivity over other materials/structures, such as poly gate, nitride or oxide and Si substrate.

In an option, the source and drain regions can be annealed after the disposable spacer are removed.

Form S/D Silicide Regions

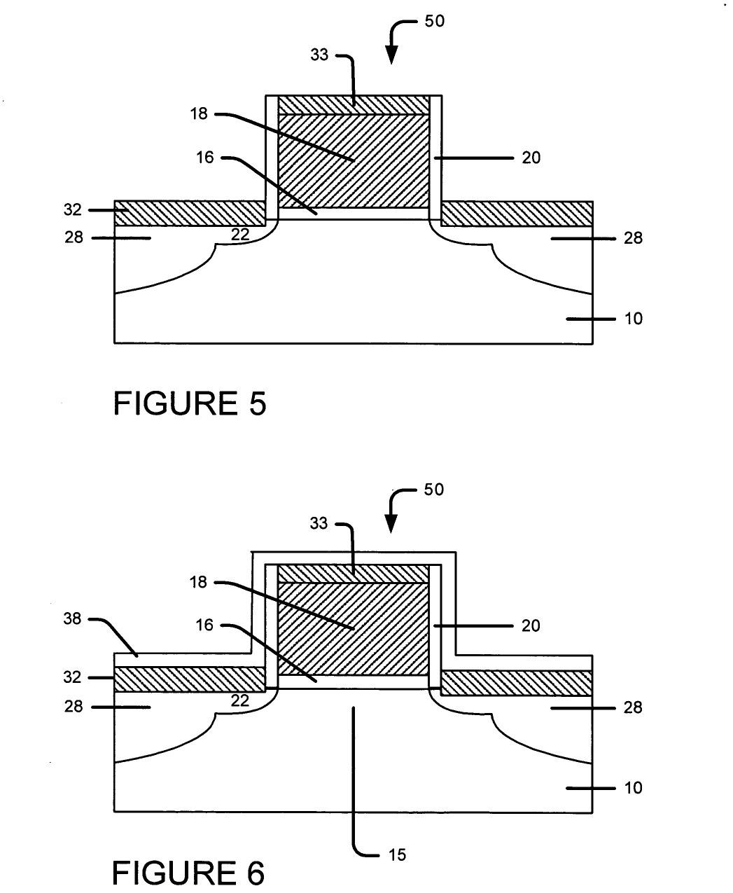

Referring to FIG. 5, we form S/D silicide regions 32 over the source and drain regions 28, and optionally form gate silicide regions 33 on the gate electrode 18. An example silicide process first forms a metal layer over the surface and then anneals the metal layer to form silicide regions where the metal is over a silicon containing surface. The unreacted metal is removed to leave the silicide regions. The disposable spacers made of organic material must be removed before the silicide process.

Form a Stress Inducing Layer

As shown in FIG. 6, we form a stress inducing layer 38 over the gate 18 and the substrate that can include regions about adjacent the gate, such as the SDE regions 22, the source and drain regions 28. The stress inducing liner provides a stress to a portion of the substrate underlying the gate electrode 18.

The stress inducing layer 38 is preferably positioned over the gate 18, the thin sidewall spacer 20, S/D silicide regions 32 and source and drain regions 28.

The stress inducing liner 38 can have a thickness ranging from about 10 nm to about 100 nm. The stress inducing liner can produce a longitudinal stress on the device channel that can range from about 200 MPa to about 2000 MPa. Although the stress inducing liner preferably is comprised of silicon nitride (Si₃N₄), the stress inducing liner may alternatively be comprised of oxide, doped oxide such as boron phosphate silicate glass, Al₂O₃, HfO₂, ZrO₂, HfSiO, and other dielectric materials that are common to semiconductor processing or any combination thereof.

A tensile stress layer can be formed for NFET devices that produces a tensile stress in the NFET channel.

A compressive stress layer can be formed for PFET devices that produces a compressive stress in the PFET channel.

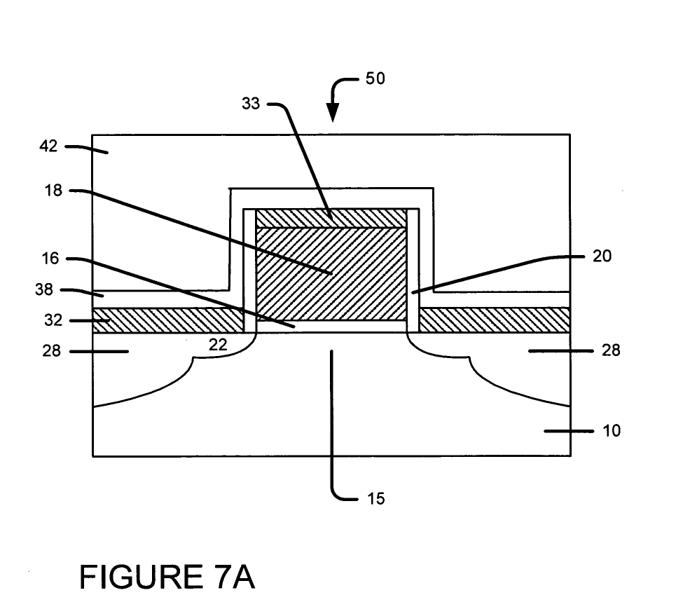

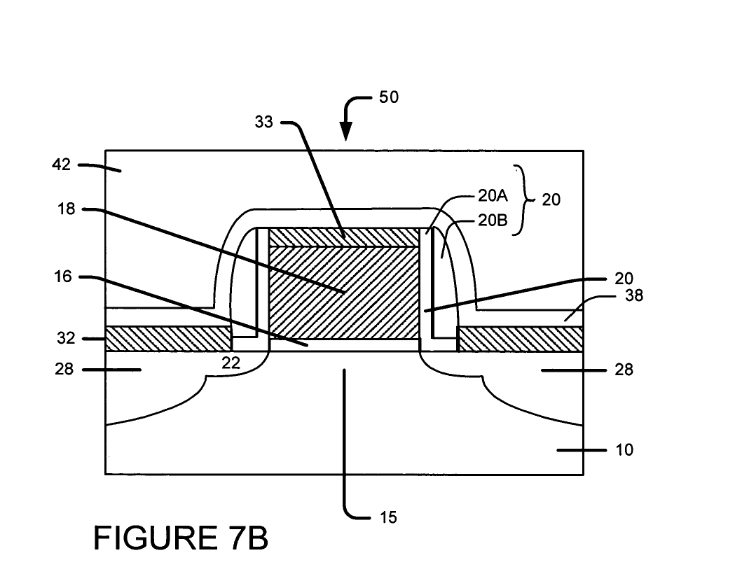

One non-limiting advantage of the inventive FET 50, as depicted in FIG. 6, (and FIG. 7B for the spacer 20A 20B option) is that the stress inducing liner 38 is in closer proximity to the channel region 15 of the device and therefore achieves a greater stress within the device channel 15. The stress inducing liner of the present embodiment is brought in close proximity to the gate region by removing the disposable spacers 24 that typically separate the stress capping layer 38 from the channel region 15.

Form ILD Dielectric Layer

Still referring to FIG. 7A, we form a (ILD) dielectric layer 42 over the substrate preferably including the stress inducing layer 38. Further processing can be used for form the semiconductor device. The interlevel dielectric layer 42 can be comprised of an oxide or low k material. Contact hole and contacts can be formed the devices. Subsequent interconnect layer and inter metal dielectric layers can be formed to interconnect devices.

FIG. 7B shows an option where the spacers 20 (20A 20B) are comprised of 2 layers.

The device can be further processed to produce more complex semiconductor devices.

### Non-Limiting Example Embodiments

The above and below advantages and features are of representative embodiments only, and are not exhaustive and/or exclusive. It should be understood that they are not representative of all the inventions defined by the claims, to be considered limitations on the invention as defined by the claims, or limitations on equivalents to the claims.

The dimensions given are for current technology and will can with future technologies. The proportions of the dimension may be relevant to future smaller technologies.

The example embodiment's disposable spacers are used to increase the overall spacer width for the S/D formation. This increases the distance of the S/D from the channel thus reducing the short channel effect without degrading Vt rolloff.

The example embodiment's organic disposable spacers (e.g., resist) are easy to remove using a resist strip process. This reduces costs and process complexity.

The example embodiment's disposable spacers, when removed post S/D formation allow a stress inducing layer to located closer to the gate and the channel. This allows the stress inducing layer to create increased stress in the channel. This increases device performance.

The example embodiments can be used in NMOS and PMOS methods and devices. The example embodiments can be used in method and devices where both N and P type devices are formed concurrently. Opposite type stress inducing layer can be formed concurrently. For example a first type stress inducing layer could be formed over the NMOS devices only and a second type stress inducing layer could be formed of the PMOS devices.

Unless explicitly stated otherwise, each numerical value and range should be interpreted as being approximate as if the word about or approximately preceded the value of the value or range.

Given the variety of embodiments of the present invention just described, the above description and illustrations show not be taken as limiting the scope of the present invention defined by the claims.

While the invention has been particularly shown and described with reference to the preferred embodiments thereof, it will be understood by those skilled in the art that various changes in form and details may be made without departing from the spirit and scope of the invention. It is intended to cover various modifications and similar arrangements and procedures, and the scope of the appended claims therefore should be accorded the broadest interpretation so as to encompass all such modifications and similar arrangements and procedures.

What is claimed is:

1. A method of forming a semiconductor device comprising:
providing at least a gate electrode over a substrate; said gate electrode has gate sidewalls; and providing first sidewall spacers over the gate sidewalls;
forming disposable spacers over the sidewalls of the first sidewall spacers; said disposable spacers are comprised of an organic material;
forming source and drain regions in said substrate;
removing said disposable spacers; and
forming S/D silicide regions over said source and drain regions.

2. The method of claim 1 which further comprises:
depositing a stress inducing layer over said gate electrode, and said source and drain regions, wherein said stress inducing layer provides a stress to a portion of said substrate underlying said gate electrode.

3. The method of claim 1 which further comprises:
depositing a stress inducing layer over said gate electrode, and said source and drain regions, wherein said stress inducing layer provides a stress to a portion of said substrate underlying said gate electrode;
forming a dielectric layer over the substrate.

4. The method of claim 1 which further comprises: the first sidewall spacers are comprised of material selected from the group consisting of dielectric material, oxide, silicon oxynitride and nitride.

5. The method of claim 1 wherein said disposable spacers are comprised of a material selected from the group consisting of photoresist, organic material, and anti-reflective coating material.

6. The method of claim 1 wherein said disposable spacers are comprised of a anti-reflective coating material;
the removal of said disposable spacers comprises an ashing plasma process.

7. The method of claim 1 wherein the removing of said disposable spacer comprises an isotropic or anisotropic etch process having a high selectivity to substantially remove said disposable spacers without removing a substantial portion of said first sidewall spacers.

8. The method of claim 1 wherein said disposable spacers are comprised of a photoresist material;
the removal of said disposable spacer comprises an wet or dry strip process.

9. The method of claim 1 wherein said stress inducing layer is comprised of a material selected from the group consisting of oxide, nitride, doped oxide, and combinations thereof.

10. The method of claim 1 wherein said stress inducing layer is deposited under conditions that produce a compressive stress to the portion of said substrate underlying said gate electrode.

11. The method of claim 1 wherein said stress inducing layer is deposited under conditions that produce a tensile stress the portion of said substrate underlying said gate electrode.

12. The method of claim 1 wherein said stress inducing layer has a thickness ranging from about 10 nm to about 100 nm.

13. The method of claim 1 wherein said first sidewall spacers are comprised of a first spacer and a second spacer.

14. The method of claim 1 which further comprises performing an implant process to form SDE regions or LDD regions approximately adjacent to said gate electrode in said substrate.

15. A method of forming a semiconductor device comprising:
forming at least a gate electrode over a substrate; said gate electrode having gate sidewalls;
forming first sidewall spacers over the gate sidewalls;
forming disposable spacers over the sidewalls of the first sidewall spacers;
said disposable spacers are comprised of a material selected from the group consisting of photoresist, organic material, and anti-reflective coating material;
forming source and drain regions in said substrate;
removing said disposable spacers; the disposable spacers are removed using an plasma process;
forming S/D silicide regions over said source and drain regions;
depositing a stress inducing layer over said gate electrode, and said source and drain regions, wherein said stress inducing layer provides a stress to a portion of said substrate underlying said gate electrode.

16. The method of claim 15 which further comprises:
forming an interlevel dielectric layer over the stress inducing layer.

17. The method of claim 15 which further comprises: the first sidewall spacers are comprised of a material selected from the group consisting a dielectric material, oxide, silicon oxynitride and nitride.

18. The method of claim 15 wherein said disposable spacers are comprised of a Anti-Reflection Coating material;
the removal of said disposable spacers comprises an ashing plasma process.

19. The method of claim 15 wherein said disposable spacers are comprised of a resist material;
the removal of said disposable spacer comprises an ashing process.

20. The method of claim 15 wherein said stress inducing layer is comprised of a material selected from the group consisting of oxides, nitrides, doped oxides, and combinations thereof.

21. The method of claim 15 wherein said stress inducing layer is deposited under conditions that produce a compressive stress to the portion of said substrate underlying said gate electrode.

22. The method of claim 15 wherein said stress inducing layer is deposited under conditions that produce a tensile stress the portion of said substrate underlying said gate electrode.

23. The method of claim 15 which further comprises performing an implant process to form SDE regions or LDD regions approximately adjacent to said gate electrode in said substrate.
